(19) United States
(12) Patent Application Publication
(10) Pub. No.: US 2026/0237451 A1
(43) Pub. Date: Aug. 13, 2026

(54) APPARATUS INCLUDING CIRCUIT USAGE DETECTION MECHANISM AND METHODS OF MANUFACTURING THE SAME

(71) Applicant: Micron Technology, Inc., Boise, ID (US)

(72) Inventor: Zhi Qi Huang, Alpharetta, GA (US)

(21) Appl. No.: 19/446,816

(22) Filed: Jan. 12, 2026

Related U.S. Application Data
(60) Provisional application No. 63/756,696, filed on Feb. 10, 2025.

(51) Int. Cl. G11C 29/50; G11C 11/4074; G11C 11/4078; G11C 29/04

(52) U.S. Cl. CPC G11C 29/50004; G11C 11/4074; G11C 11/4078; G11C 2029/0403; G11C 2029/5004; G11C 2029/5006

(57) ABSTRACT

Methods, apparatuses, and systems related to tracking a status of a health monitor are described. An apparatus includes a mirrored path of components configured to generate a mirrored current that is in direct proportion to a load current provided to the health monitor. The apparatus includes additional circuitry configured to monitor the mirrored current to determine one or more statuses for the health monitor, circuitry tracked by the health monitor, or both.

### CROSS-REFERENCE TO RELATED APPLICATIONS

The present application claims priority to U.S. Provisional Patent Application No. 63/756,696, filed Feb. 10, 2025, the disclosure of which is incorporated herein by reference in its entirety.

### TECHNICAL FIELD

The disclosed embodiments relate to apparatuses, and, in particular, to semiconductor devices with a mechanism for detecting usage, such as a degree/frequency or a magnitude of usage, of an electrical circuit.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data. For example, the memory devices can include Double Data Rate (DDR) RAM devices that implement DDR interfacing scheme (e.g., DDR4, DDR5, etc.) for high-speed data transfer.

With technological advancements in other areas and increasing applications, the market is continuously looking for faster, more efficient, smaller, and more reliable devices. To meet the market demand, the semiconductor devices are being pushed to the limit with various improvements. Improving devices, generally, may include increasing circuit density, increasing operating speeds or otherwise reducing operational latency, increasing reliability, increasing data retention, reducing power consumption, or reducing manufacturing costs, among other metrics. However, such improvements can often introduce challenges in reliability and longevity.

### BRIEF DESCRIPTION OF THE DRAWINGS

FIG. 1 is a block diagram of a housing system including a computing device in accordance with an embodiment of the present technology.

FIG. 2 is a block diagram of an apparatus in accordance with an embodiment of the present technology.

FIG. 3 is a circuit diagram of an example a usage detection mechanism in accordance with an embodiment of the present technology.

FIG. 4 is a flow diagram illustrating an example method of manufacturing an apparatus in accordance with an embodiment of the present technology.

FIG. 5 is a schematic view of a system that includes an apparatus configured in accordance with embodiments of the present technology.

### DETAILED DESCRIPTION

As described in greater detail below, the technology disclosed herein relates to an apparatus, such as for memory systems, systems with memory devices, related methods, etc., for detecting usage of an electrical circuit. As an illustrative example, the apparatus can be a part of a computing system incorporated within a housing system (e.g., a larger encompassing machine/system), such as a vehicle. The usage of the housing system can provide a context for requiring a functional safety mechanism for and/or through the computing system. For the vehicle example, the functional safety mechanism can include Functional Safety (FuSa) applicable for critical system, such as those involving control functions or power generation/distribution systems, requiring the absence or requirement for removing certain risks due to hazards caused by malfunctioning behavior of electrical systems.

To enable the functional safety mechanism, the computing system can include a health monitor having a sensor array configured monitors various aspects of the electrical system. Unfortunately, the sensor array itself may be prone to wear, degradation, and failure. Often, the performance and/or the longevity of the sensor array may depend on a usage pattern for the housing system.

Accordingly, embodiments of the technology described below includes a usage detection mechanism configured to track the health monitor (e.g., the sensor array therein) for usage indications. In some embodiments, the usage detection mechanism can include an overload detection circuit configured to mirror a power/current supplying circuit path (e.g., according to a stepdown ratio). The overload detection circuit can have components that are physically configured (e.g., sized) according to the stepdown ratio, thus mimicking a fraction of a load current supply through the power supplying path to a load (e.g., the sensor array). The mirroring and the stepdown ratio can be implemented using a mirror control device (e.g., a clamping amplifier) and a load driving capacity (e.g., a physical size of a controlling device, such as a PMOS). The overload detection circuit can indicate an abnormal usage of the housing system, such as through detecting an overload state corresponding to a load current exceeding an overload threshold.

### Example Application

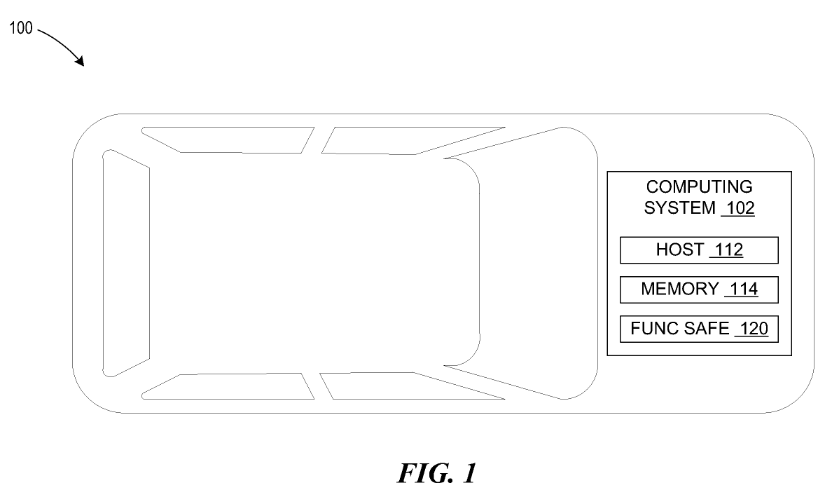

FIG. 1 is a block diagram of a housing system 100 including a computing device 102 in accordance with an embodiment of the present technology. The housing system 100 can correspond to an overall application or context for the computing device 102. The housing system 100 can include a machine, a vehicle, a system, and/or the like. Examples of the housing system 100 can include aerospace and/or defense applications, vehicles (e.g., automobiles, flight vehicles, marine vehicles, etc.), industrial machinery, medical device, consumer vehicles, etc.

The computing device 102 can include electrical circuitry attached to or integral with the housing system 100. The computing device 102 can be configured to control functions and/or operations of the housing system 100. Moreover, the computing device 102 can be configured to monitor various aspects of the housing system 100. For applications in vehicles, the computing device 102 can include a flight computer, a navigation system, a vehicle control/management system, an electronic control unit (ECU), and/or the like.

The computing system 102 can include a host 112, such as a central processing unit (CPU), a graphics processing unit (GPU), and/or other similar logic, computational circuits, or processors. The computing system 102 can further include a memory 114 configured to store data. The memory 114 can include transient memory, non-transient memory, or a combination thereof. For example, the memory 114 can include DRAM, static RAM (SRAM), NAND memory, NOR memory, and/or the like.

In some embodiments, the housing system 100 and the computing system 100 therein can be configured to adhere to and implement a functional safety mechanism 120. The functional safety mechanism 120 can include configurations (e.g., circuits, devices, software, firmware, etc.) for providing a targeted level of performance and resilience, thereby improving and preserving an expected level of performance and related safety. For the vehicular application, the functional safety mechanism 120 can correspond to the configurations that correspond to safety requirements associated with the absence of unacceptable or identified risks arising from issues caused by malfunctioning of electrical and/or computing systems. Accordingly, the functional safety mechanism 120 can include hardware and/or software elements configured to prevent systematic failures, detect and control hardware and/or software failures, or the like. Details regarding the computing system 100 can the functional safety mechanism 120 are described below.

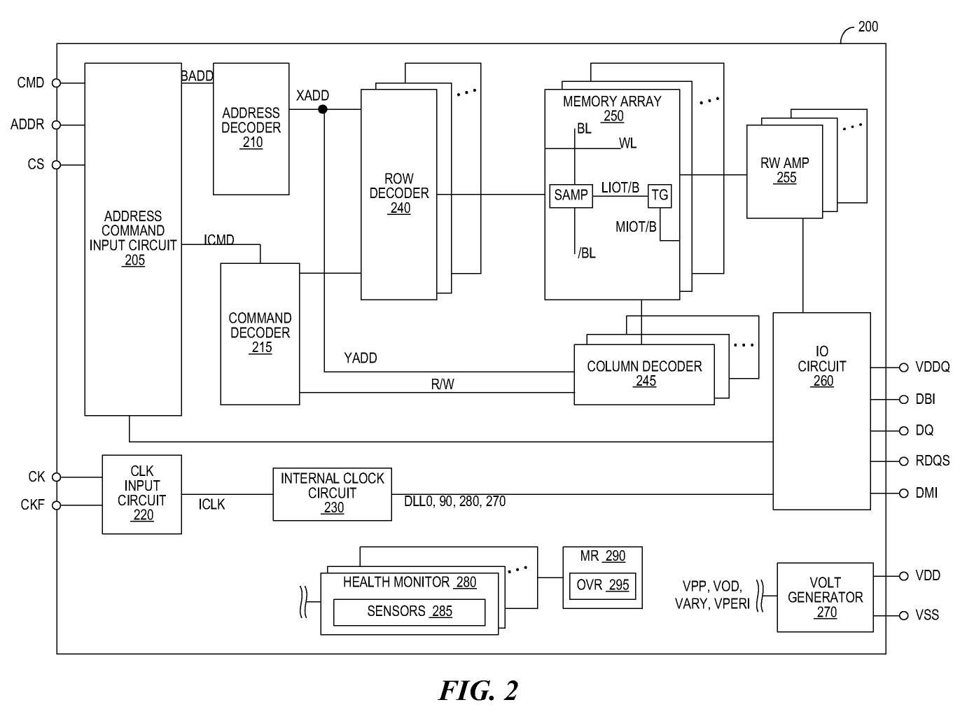

FIG. 2 is a block diagram of the apparatus 200 (e.g., a semiconductor die assembly, including a 3DI device or a die-stacked package) in accordance with an embodiment of the present technology. For example, the apparatus 200 can include a DRAM (e.g., DDR4 DRAM, DDR5 DRAM, LP DRAM, HBM DRAM, etc.), or a portion thereof that includes one or more dies/chips. In some embodiments, the apparatus 200 can include synchronous DRAM (SDRAM) of DDR type integrated on a single semiconductor chip. The apparatus 200 can correspond to the memory 114 of FIG. 1 or a portion thereof.

The apparatus 200 may include an array of memory cells, such as memory array 250. The memory array 250 may include a plurality of banks (e.g., banks 0–15), and each bank may include a plurality of word lines (WL), a plurality of bit lines (BL), and a plurality of memory cells arranged at intersections of the word lines and the bit lines. Memory cells can include any one of a number of different memory media types, including capacitive, magnetoresistive, ferroelectric, phase change, or the like. The selection of a word line WL may be performed by a row decoder 240, and the selection of a bit line BL may be performed by a column decoder 245. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The memory array 250 may also include plate lines and corresponding circuitry for managing their operation.

The apparatus 200 may employ a plurality of external terminals that include command and address terminals coupled to a command bus and an address bus to receive command signals (CMD) and address signals (ADDR), respectively. The apparatus 200 may further include a chip select terminal to receive a chip select signal (CS), clock terminals to receive clock signals CK and CKF, data terminals DQ, RDQS, DBI, and DMI, power supply terminals VDD, VSS, and VDDQ.

The command terminals and address terminals may be supplied with an address signal and a bank address signal (not shown in FIG. 2) from outside. The address signal and the bank address signal supplied to the address terminals can be transferred, via a command/address input circuit 205 (e.g., command circuit), to an address decoder 210. The address decoder 210 can receive the address signals and supply a decoded row address signal (XADD) to the row decoder 240, and a decoded column address signal (YADD) to the column decoder 245. The address decoder 210 can also receive the bank address signal and supply the bank address signal to both the row decoder 240 and the column decoder 245.

The command and address terminals may be supplied with command signals (CMD), address signals (ADDR), and chip select signals (CS), from a memory controller. The command signals may represent various memory commands from the memory controller (e.g., including access commands, which can include read commands and write commands). The chip select signal may be used to select the apparatus 200 to respond to commands and addresses provided to the command and address terminals. When an active chip select signal is provided to the apparatus 200, the commands and addresses can be decoded and memory operations can be performed. The command signals may be provided as internal command signals ICMD to a command decoder 215 via the command/address input circuit 205. The command decoder 215 may include circuits to decode the internal command signals ICMD to generate various internal signals and commands for performing memory operations, for example, a row command signal to select a word line and a column command signal to select a bit line.

Read data can be read from memory cells in the memory array 250 designated by row address (e.g., address provided with an active command) and column address (e.g., address provided with the read). The read command may be received by the command decoder 215, which can provide internal commands to input/output circuit 260 so that read data can be output from the data terminals DQ, RDQS, DBI, and DMI via read/write amplifiers 255 and the input/output circuit 260 according to the RDQS clock signals.

Write data can be supplied to the data terminals DQ, DBI, and DMI. The write command may be received by the command decoder 215, which can provide internal commands to the input/output circuit 260 so that the write data can be received by data receivers in the input/output circuit 260 and supplied via the input/output circuit 260 and the read/write amplifiers 255 to the memory array 250. The write data may be written in the memory cell designated by the row address and the column address.

The power supply terminals may be supplied with power supply potentials VDD and VSS. These power supply potentials VDD and VSS can be supplied to an internal voltage generator circuit 270. The internal voltage generator circuit 270 can generate various internal potentials VPP, VOD, VARY, VPERI, and the like based on the power supply potentials VDD and VSS. The internal potential VPP can be used in the row decoder 240, the internal potentials VOD and VARY can be used in the sense amplifiers included in the memory array 250, and the internal potential VPERI can be used in many other circuit blocks.

The power supply terminal may also be supplied with power supply potential VDDQ. The power supply potential VDDQ can be supplied to the input/output circuit 260 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 260 so that power supply noise generated by the input/output circuit 260 does not propagate to the other circuit blocks.

The clock terminals and data clock terminals may be supplied with external clock signals and complementary external clock signals. The external clock signals CK, CKF can be supplied to a clock input circuit 220 (e.g., external clock circuit). The CK and CKF signals can be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 220 can receive the external clock signals. For example, when enabled by a clock/enable signal from the command decoder 215, an input buffer can receive the clock/enable signals. The clock input circuit 220 can receive the external clock signals to generate internal clock signals ICLK. The internal clock signals ICLK can be supplied to an internal clock circuit 230.

Additionally, the apparatus 200 can include a health monitor 280 configured to track targeted conditions at one or more portions within the apparatus 200, one or more portions one or more portions within the computing system 102 of FIG. 1, within the housing system 100 of FIG. 1 (e.g., other localized electrical circuits within the vehicle). The health monitor 280 can include sensors 285 that detect statuses (e.g., active/non-active, passing/failure, process pass/fail, etc.) or measurements (e.g., temperature, consumed power, response rate, etc.) from the tracked portions. In some embodiments, the health monitor 280 can be included within the packaging or the casing associated with the apparatus 200. In other embodiments, the health monitor 280 can be configured to alternatively or additionally track conditions outside of the apparatus 200 and be located external to but communicatively coupled with the apparatus 200.

The health monitor 280 can be coupled to a corresponding mode register 290 configured to indicate a status of the health monitor 280. For example, the mode register 290 can indicate whether there any issues are detected with the operation of the health monitor 280. In one vehicular application, the mode register 290 can correspond to MR123 OP[6]. Accordingly, the apparatus 200 (e.g., using a portion within the health monitor 280 or a separate circuit) that generates an over usage detection 295 representative of one or more targeted issues with the health monitor 280. The targeted issues with the health monitor 280 can include a status or a condition of one or more corresponding sensors, and such condition/status of the sensors 285 can indicate a health or even a frequently occurring event associated with the sensed portion.

The over usage detection 295 can correspond to the value of the mode register 290 or a transition thereof. In other words, in response to detecting one or more issues with the health monitor 280, the apparatus 200 can generate the over usage detection 295 by changing a value of one or more bits within the mode register 290. As described, the over usage detection 295 can be representative of the health of the monitor 280, the sensors 285 therein, and/or the corresponding portions within the apparatus 200/system 102/system 100 tracked by the sensors 285. Accordingly, the apparatus 200 can signal the represented issues to the host 112 using the over usage detection 295 and the mode register 290.

### Example Over Usage Detection Mechanism

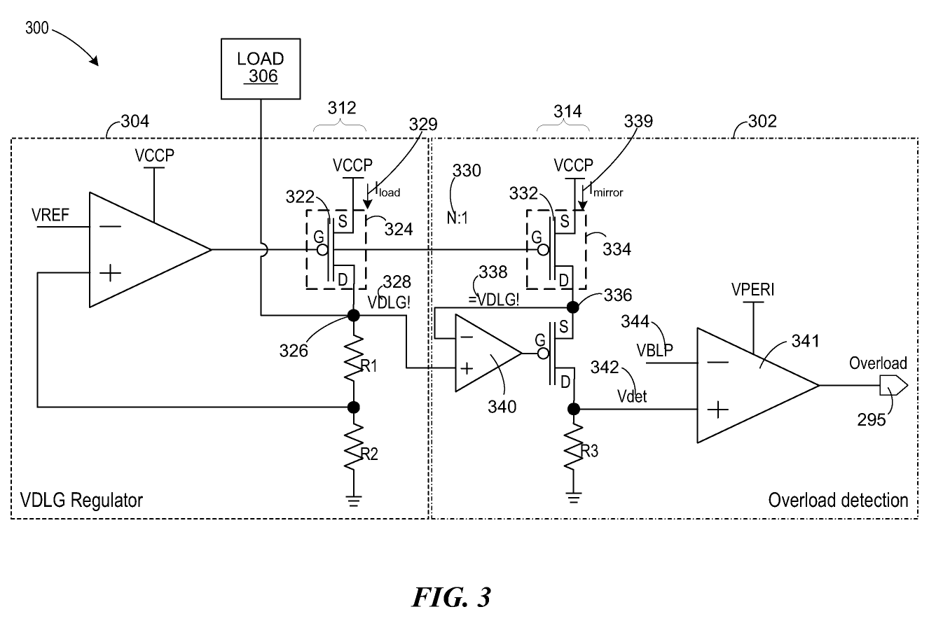

FIG. 3 is a circuit diagram of an example a usage detection mechanism 300 in accordance with an embodiment of the present technology. The usage detection mechanism 300 can be configured to track the status of the health monitor 280 of FIG. 2 and/or the sensors 285 therein. The usage detection mechanism 300 can generate the over usage detection 295 of FIG. 2. In some embodiments, the usage detection mechanism 300 or a portion thereof can be incorporated or implemented within the health monitor 280, the apparatus 200, and/or the computing system 100 of FIG. 1. In other embodiments, the usage detection mechanism 300 or a portion thereof can be implemented external to the health monitor 280 and/or the apparatus 200.

In some embodiments, the usage detection mechanism 300 can include an an overload detection circuit 302 coupled to and monitoring a monitor-input regulator 304. The monitor-input regulator 304 can be coupled to a system voltage supply, such as a VCC pumped voltage (VCCP) typically used as wordline voltage. Using the system high voltage, the monitor-input regulator 304 can provide a regulated or a controlled input power for a load 306, which may include the health monitor 280 and/or the sensors 285 therein.

As illustrated in FIG. 3, the monitor-input regulator 304 can include a load current path 312 having a load driving component 322 (e.g., a switch/transistor) connected to the system voltage supply VCCP and configured to control a current flowing from the supply to the load 306. In some embodiments, the load driving component 322 can include a PMOS transistor with a source terminal connected to the VCCP. The opposing terminal (e.g., according to the current channel) of the load driving component 322 can be connected to the load 306 and one or more resistors (e.g., R1 and R2) before an electrical ground.

The output terminal of the load driving component 322 can be coupled to a controlling component, such a comparator, that controls an operating state of the load driving component 322. For example, during operation, the load current path 312 can produce a loading current 329 according to the power consumed by the load 306. The loading current 329 can be measured at a node between R1 and R2 according to a voltage drop across R2. For example, the voltage drop across R2 can directly represent the loading current 329 according to the resistance of R1 and/or R2. The controlling component can compare the R2 voltage to a reference (VREF) and control operation of the load driving component 322 accordingly (e.g., through actively manipulating gate voltage and/or through controlling saturation state of the load driving component 322).

The load current path 312 can be coupled to a mirrored path 314 that mimics or replicates the behavior of the load current path 312 at a different magnitude or scale. To reduce the power consumed in detecting the over usage detection 295, the mirrored path 314 can generate a mirrored current 339 that corresponds to a fraction of the loading current 329 according to a stepdown ratio 330. In other words, the mirrored path 314 can be configured to generate the mirrored current 339 that directly reflects the loading current 329 at a reduced magnitude corresponding to the stepdown radio 330. For example, the stepdown ratio 330 can correspond to N:1, with N (2, 10, 20, 50, 100, or any number greater than 1) representing the scale of the load current 329 and value 1 representing the reflected scale of the mirrored current 339. Stated differently, the mirrored current 339 can be 1/N of the load current 329.

The mirrored path 314 can include a mirrored control component 332 corresponding to the load driving component 322. For example, the mirrored control component 332 can match a type, a category, a connection, or a combination thereof for the load driving component 322. In some embodiments, the load driving component 322 and the mirrored control component 332 can both include PMOS transistors with the source terminals connected to the same voltage supply (e.g., VCCP).

The mirrored control component 332 can differ in one or more characteristics in comparison to the load driving component 322 according to the stepdown ratio 330. For example, the load driving component 322 can have a load driving capacity 324 that differs from a mirrored capacity 334 of the mirrored control component 332. In some embodiments, the load driving capacity 324 and the mirrored capacity 334 can both correspond a physical size/footprint or doping characteristic of the corresponding PMOS transistor, and the difference can match or be proportional to the stepdown ratio 330 (e.g., N:1 sizing or doping characteristic).

The mirrored path 314 can have the mirrored control component 332 connected to a control circuitry configured to ensure accuracy for the mirrored current 329 and track the loading current 329. For example, the mirrored path 314 can include a current control component (e.g., another PMOS) connected at a drain terminal of the mirrored control component 332. The current control component can be configured to ensure that the mirrored current 339 matches the loading current 329 according to the stepdown ratio 330. The output of the current control component can be connected to a mirrored measuring resistor R3.

In further controlling the proportioned match between the mirrored current 339 and the loading current 329, the mirrored path 314 can be connected to the load current path 312 through a linking component 340. The linking component 340 can include a circuit component configured to match a performance metric, such as an input voltage 328 (VDLG!) at node 326 and into the load 306, across the load current path 312 and the mirror current path 314. For example, the control component 332 can be configured to ensure that a mirroring voltage 338 at a reflected node 326 (e.g., the drain terminal) of the mirrored control component 332 matches (=VDLG!) the input voltage 328 supplied to the load 306. In some embodiments, the linking component 340 can include a clamping amplifier with one (e.g., negative) terminal connected to the mirroring voltage 338 and another (e.g., positive) terminal connected to the load input voltage 328. The output of the control component 332 can be connected to the gate of the current control component, thereby controlling the flow of mirrored current 339 according to a comparison between the load input voltage 328 and the mirroring voltage 338.

The overload detection circuit 302 can measure the carefully replicated/tracked mirrored current 339 of the mirrored path 314. For example, the mirrored path 314 can include a resistor R3 between the current control component and electrical ground. With a known resistance value of R3, the corresponding node can produce a detection voltage 342 that directly represents the mirrored current 339. The overload detection circuit 302 can include an overload detection component 341 (e.g., a comparator) that generates the over usage detection signal 295 based on comparing the detection voltage 342 to a detection reference 344. For the example shown in FIG. 3, the detection reference 344 can include a bitline precharge voltage VBLP, and the R3 resistor can have a resistance value such that the threshold voltage 342 becomes an upper threshold directly corresponding to an overloading threshold for the mirrored current 339. In one or more embodiments, the detection reference 344 (e.g., the threshold for the over usage detection 295) can correspond to a threshold current of 3-4 mA.

In returning to the FuSa implementation, the health monitor 280 and/or the sensors 285 therein can draw a predictable amount of current (e.g., the loading current 329) when the circuit is in a healthy and satisfactory condition. However, when the circuits/portions monitored by the health monitor 280 operates in certain modes, such operation may cause stress on the health monitor 280. Additionally, any defects that may have been unnoticed or negligible during qualification may be worsened prematurely during the deployed operation of the apparatus 200. As a result of the real-time over usage and/or the resulting stress and damage over time, the health monitor 280 may draw a higher level of the loading current 329 that is representative of an overloading state. Using the various aspects of the mirrored path 314 and the linking component 340, the mirrored current 339 can accurately represent the loading current 329. When the loading current 329 reaches the overloading condition, the mirrored current 339 can produce a detection voltage 342 that meets or exceeds the detection reference 344. In response, the overload comparator 341 can generate the over usage detection 295, such as by transitioning a corresponding bit for the mode register 290 of FIG. 2.

The overload usage detection 295 can be communicated to or read by host 112 of FIG. 1, and the host 112 can implement a predetermined response action. For example, the host 112 can notify an operator, a designer, or the like of the housing system 100 of FIG. 1 and/or implement predetermined failure recovery/management processes according to the functional safety mechanism 120 of FIG. 1.

### Example Manufacturing Flow

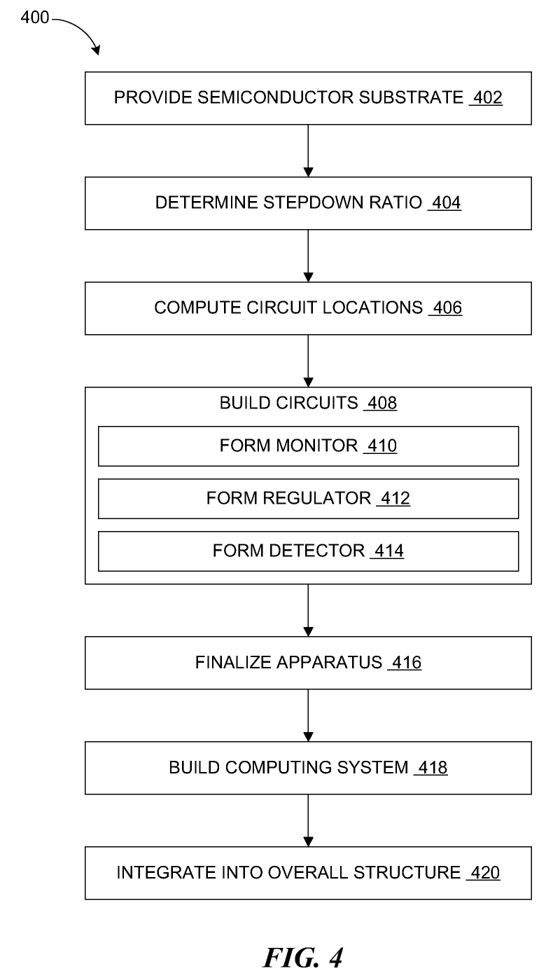

FIG. 4 is a flow diagram illustrating an example method of manufacturing 400 an apparatus (e.g., the system 100 of FIG. 1, the computing system 102 of FIG. 1, the memory 114 of FIG. 1, the apparatus 200 of FIG. 2, the usage detection mechanism 300 of FIG. 3, a portion thereof, or a combination thereof) in accordance with an embodiment of the present technology. The method can correspond to building and installing a circuit configured to detect usage and generate the corresponding over usage detection 295 of FIG. 2.

At block 402, the method 400 can include providing a semiconductor (e.g., silicon) substrate. The substrate can be positioned and prepared for circuit formation, such as dopant implantation, masking, etching, metallization, etc. for building circuits thereon.

At block 404, the method 400 can include determining a stepdown ratio (e.g., the stepdown ratio 330 of FIG. 3) for detecting the usage. For example, the stepdown ratio can be determined based on computing a targeted ratio between the load driving capacity 324 of FIG. 3 (e.g., the physical size requirement for the PMOS) and the mirror capacity 334 of FIG. 3 (e.g., the corresponding physical size requirement) as allowed by the overall performance requirements. Also, determining the stepdown ratio can include accessing the stepdown ratio 330 that has been predetermined by a designer, a computer model, a manufacturer, etc.

At block 406, the method 400 can include computing the circuit locations. For example, the circuit locations can be computed based on accessing or determining layout for the overload detection circuit 302 of FIG. 3, the monitor-input regulator 304 of FIG. 3, the circuits of the apparatus 200, or a combination thereof on the substrate. The circuit layout can be computed using one or more computer tools/models. Also, the circuit layout can be accessed through records or provided designs.

At block 408, the method 400 can include building the circuits on the substrate according to the computed circuit locations. Building the circuits can include forming the monitor (block 410), forming the regulator (block 412), and forming the detector (block 414). The method 400 can accordingly form overload detection circuit 302, the monitor-input regulator 304, the mirrored control component 332 of FIG. 3, the overload comparator 341, or a combination thereof described above.

At block 416, the method 400 can include finalizing the apparatus (e.g., the apparatus 200/the memory 114, such as the DRAM). The apparatus can be finalized by forming the circuit components illustrated in FIG. 2 and described above. Also, finalizing the circuit can include forming pads, protective layers, encapsulations, etc. Moreover, finalizing can include singulating the dies from the processed substrate. Accordingly, the finalized component can include the apparatus 200, the memory 114, or the like.

At block 418, the method 400 can include building the computing system 102. In some embodiments, building the computing system 102 (e.g., the ECU) can include mounting the host 112 of FIG. 1, the memory 114, or a combination thereof on a printed circuit board.

At block 420, the method 400 can include integrating the computing system 102 into an overall structure (e.g., the housing system 100). For example, the integration can include attaching the computing system 100 to a vehicle chassis and connecting other circuits and components within the corresponding vehicle.

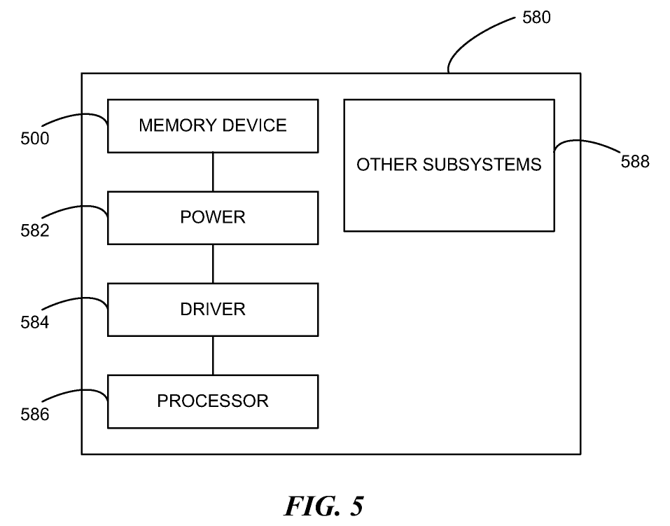

FIG. 5 is a flow diagram illustrating an example method 500 of operating an apparatus (e.g., the system 100 of FIG. 1, the apparatus 100 of FIG. 1) in accordance with an embodiment of the present technology. The method 500 can be for selectively controlling a delay between operations (e.g., DQ and DQS). The method 500 can correspond to any of the circuits (e.g., the coordination circuit 300 of FIG. 3) and/or the timing diagrams (e.g., the timing diagram 400 of FIG. 4) described above.

FIG. 5 is a schematic view of a system that includes an apparatus in accordance with embodiments of the present technology. Any one of the foregoing apparatuses (e.g., memory devices) described above with reference to FIGS. 1-4 can be incorporated into or implemented in memory (e.g., a memory device 500) or any of a myriad of larger and/or more complex systems, a representative example of which is system 580 shown schematically in FIG. 5. The system 580 can include the memory device 500, a power source 582, a driver 584, a processor 586, and/or other subsystems or components 588. The memory device 500 can include features generally similar to those of the apparatus described above with reference to FIGS. 1-5 and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer’s or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-5.

We claim:

1. A memory configured to operate within a vehicle, the memory comprising:
a memory array;
a health monitor having a set of sensors and configured to track operating conditions of the memory;
a monitor-input regulator coupled to the health monitor and configured to supply a loading current for operating the health monitor, wherein the monitor-input regulator includes a load driving component disposed between (1) a system input supply VCCP and (2) the health monitor; and
an overload detection circuit coupled to the health monitor and the monitor-input regulator and configured to provide a mirrored current that is in direct proportion to the loading current,
wherein the overload detection circuit includes a mirrored control component disposed between (1) the system input supply VCCP and (2) an overload comparator configured to indicate an over usage detection when the mirrored current meets or exceeds a predetermined reference threshold.

2. The memory of claim 1, wherein the overload detection circuit includes a clamping amplifier having:
a first input connected to a load node corresponding to a connection between the health monitor and the monitor-input regulator;
a second input connected to a mirror node corresponding to a connection between the mirrored control component and a current flow controller that is subsequently coupled to an electrical ground; and
an output connected to a control terminal of the current flow controller, wherein the output and the current flow controller are configured to maintain a voltage at the mirror node to match a loading voltage at the load node.

3. The memory of claim 1, wherein:
the load driving component is a first PMOS transistor having a first physical size; and
the mirrored control component is a second PMOS transistor having a second physical size corresponding to the direct proportion relative to the first physical size, wherein the direct proportion between the first and second physical sizes at least partially corresponds to the direct proportion between the loading current and the mirrored current.

4. The memory of claim 1, wherein:
the system input supply VCCP is a VCC pumped voltage used as wordline voltage in operating the memory array;
the overload detection circuit includes a resistor configured to generate a detection voltage based on the mirrored current traversing through the resistor; and
the overload comparator includes (1) a first input connected to the resistor and (2) a second input connected to the predetermined reference threshold,
wherein the predetermined reference threshold is a bitline precharge voltage (VBLP) in operating the memory array,
wherein the overload comparator is configured to generate the over usage detection when the detection voltage meets or exceeds the VBLP.

5. The memory of claim 1, wherein the overload detection circuit is configured to adjust the predetermined reference threshold using an on-die trim for generating the over usage detection.

6. The memory of claim 1, wherein the memory is a Dynamic Random-Access Memory (DRAM).

7. The memory of claim 6, wherein the memory comprises an Electronic Control Unit (ECU) of the vehicle.

8. The memory of claim 7, wherein:
the overload detection circuit is configured to according to a Functional Safety (FuSa) requirement; and
the overload detection circuit is configured to transition a bit for a mode register (MR123 OP[6]) based on the over usage detection.

9. The memory of claim 7, wherein the over usage detection represents a degradation in the sensors resulting in the loading current exceeding an operating threshold and a usage pattern for components monitored by the sensors.

10. The memory of claim 7, wherein the ECU further comprising a host that is configured to:
detect the over usage detection indicated by the memory; and
in response to the over usage detection, generate a message and/or incapacitate the vehicle before operation thereof.

11. A method of manufacturing a memory device configured to operate within a vehicle, the method comprising:
providing a semiconductor substrate;
forming circuitry on the semiconductor substrate, the circuitry including:
a memory array;
a health monitor having a set of sensors and configured to track operating conditions of the memory;
a monitor-input regulator coupled to the health monitor and configured to supply a loading current for operating the health monitor, wherein the monitor-input regulator includes a load driving component disposed between (1) a system input supply VCCP and (2) the health monitor;
an overload detection circuit coupled to the health monitor and the monitor-input regulator and configured to generate a mirrored current that is in direct proportion to the loading current,
wherein the overload detection circuit includes a mirrored control component disposed between (1) the system input supply CCP and (2) an overload comparator configured to indicate an over usage detection when the mirrored current meets or exceeds a predetermined reference threshold; and
singulating the semiconductor substrate to manufacture the memory including the circuitry.

12. The method of claim 11, wherein forming the circuitry having the overload detection circuit includes forming a clamping amplifier having:
a first input connected to a load node corresponding to a connection between the health monitor and the monitor-input regulator;
a second input connected to a mirror node corresponding to a connection between the mirrored control component and a current flow controller that is subsequently coupled to an electrical ground; and
an output connected to a control terminal of the current flow controller, wherein the output and the current flow controller are configured to maintain a voltage at the mirror node to match a loading voltage at the load node.

13. The method of claim 11, wherein forming the circuitry includes:
forming a first transistor as the load driving component, the first transistor corresponding to a type and having a first physical size; and
forming a second transistor as the mirrored control component, the second transistor corresponding to the type and having a second physical size corresponding to the direct proportion relative to the first physical size, wherein the direct proportion between the first and second physical sizes at least partially corresponds to the direct proportion between the loading current and the mirrored current.

14. The method of claim 11, wherein, for the formed circuitry:
the system input supply VCCP is a VCC pumped voltage used as wordline voltage in operating the memory array;
the overload detection circuit includes a resistor configured to generate a detection voltage based on the mirrored current traversing through the resistor; and
the overload comparator includes (1) a first input connected to the resistor and (2) a second input connected to the predetermined reference threshold,
wherein the predetermined reference threshold is a bitline precharge voltage (VBLP) in operating the memory array,
wherein the overload comparator is configured to generate the over usage detection when the detection voltage meets or exceeds the VBLP.

15. An apparatus, comprising:
functional circuitry;
a health monitor having a set of sensors and configured to track operating conditions of the functional circuitry;
a load driving component connected between an input supply and the health monitor, the load driving component configured to provide a loading current and load voltage to the health monitor;
a mirrored control component connected to the input supply and configured to provide a mirrored current that is in direct proportion to the loading current;
a linking component connected to the load driving component and the mirrored control component, the linking component configured to duplicate the load voltage at an output of the load driving component; and
an overload comparator configured to indicate an over usage detection when the mirrored current meets or exceeds a predetermined reference threshold, wherein the over usage detection represents degradation in the set of sensors.

16. The apparatus of claim 15, further comprising:
a mirrored current controller coupled between (1) the output of the load driving component and (2) the overload comparator and electrical ground,
wherein the mirrored current controller and the linking component configured to duplicate the load voltage at the output of the load driving component and provide a detection voltage to the overload comparator.

17. The apparatus of claim 15, further comprising:
the load driving component is a first transistor corresponding to a type and having a first physical size; and
the mirrored control component is a second transistor corresponding to the type and having a second physical size corresponding to the direct proportion relative to the first physical size, wherein the direct proportionality between the first and second physical sizes at least partially corresponds to the direct proportionality between the loading current and the mirrored current.

18. The apparatus of claim 15, wherein:
the input supply and the predetermined reference threshold are both correspond to different voltages used to operate the functional circuitry; and
the input supply is greater than the predetermined reference threshold.

19. The apparatus of claim 15, wherein the predetermined reference threshold is adjustable after manufacturing of the apparatus using a trim function for the apparatus.

20. The apparatus of claim 15, wherein over usage detection further represents a usage pattern for the functional circuitry.
